(19) United States
(12) Patent Application Publication
(10) Pub. No.: US 2025/0374781 A1
(43) Pub. Date: Dec. 4, 2025

(54) DISPLAY DEVICE AND ELECTRONIC DEVICE INCLUDING THE SAME

(71) Applicant: Samsung Display Co., Ltd., Yongin-si (KR)

(72) Inventor: SEO-YEON Kim, Yongin-si (KR)

(21) Appl. No.: 19/084,759

(22) Filed: Mar. 20, 2025

(30) Foreign Application Priority Data
Jun. 4, 2024 (KR) 10-2024-0073302

(51) Int. Cl. H10K 59/131; H10K 59/124

(52) U.S. Cl. CPC H10K 59/131; H10K 59/124

(57) ABSTRACT

A display device may include a substrate including a display area and a peripheral area disposed outside a display area, a light-emitting element disposed on the display area of the substrate, a static electricity prevention layer configured to cover a side surface of the substrate, and a static electricity test wire disposed on the peripheral area, where the static electricity test wire may include a plurality of first test wires spaced apart from each other and connected to the static electricity prevention layer, respectively, and a second test wire electrically connected to the plurality of first test wires.

This application claims priority to Korean Patent Application No. 10-2024-0073302, filed on Jun. 4, 2024, and all the benefits accruing therefrom under 35 U.S.C. § 119, the content of which in its entirety is herein incorporated by reference.

### BACKGROUND

### 1. Field

The disclosure relates to a display device.

### 2. Description of the Related Art

The display device is a device that displays a screen, and includes a liquid crystal display (“LCD”), an organic light-emitting display (“OLED”) device, or the like. These display devices are widely used in various electronic devices, such as mobile phones, navigation devices, digital cameras, electronic books, portable game consoles, or various terminals.

For example, an organic light-emitting display device includes two electrodes and an organic light-emitting layer positioned between them, and electrons injected from one electrode and holes injected from the other electrode combine in the organic light-emitting layer, thereby forming excitons. As the exciton changes from the excited state to the ground state, it releases energy and emits light.

Organic light-emitting display devices are self-luminous display devices, and unlike liquid crystal displays, a separate light source is not desired in the organic light-emitting display devices, which thereby may be manufactured in a lightweight and thin form. In addition, organic light-emitting display devices are not only advantageous in terms of power consumption due to low voltage operation, but also have excellent color reproduction, response speed, viewing angle, and contrast ratio, and are expected to be utilized in various fields.

### SUMMARY

The disclosure attempts to provide a display device capable of improving reliability.

A display device may include a substrate including a display area and a peripheral area disposed outside a display area, a light-emitting element disposed on the display area of the substrate, a static electricity prevention layer configured to cover a side surface of the substrate, and a static electricity test wire disposed on the peripheral area, where the static electricity test wire may include a plurality of first test wires spaced apart from each other and connected to the static electricity prevention layer, respectively, and a second test wire electrically connected to the plurality of first test wires.

In an embodiment, ends of the plurality of first test wires may be aligned with an end of the substrate.

In an embodiment, the plurality of first test wires may be repeatedly arranged on an end of the substrate.

In an embodiment, the display device may further include a dam disposed on the peripheral area of the substrate, and a crack test wire disposed between the dam and the static electricity test wire.

In an embodiment, the second test wire may be disposed between the plurality of first test wires and the crack test wire.

In an embodiment, the static electricity test wire may be disposed in a same layer as the crack test wire and may include a same material as that of the crack test wire.

In an embodiment, each of the plurality of first test wires may include horizontal portions in contact with the static electricity prevention layer and an extension portion connecting between the horizontal portions.

In an embodiment, the display device may further include a first gate insulating layer disposed on the substrate, and a second gate insulating layer disposed on the first gate insulating layer, where the plurality of first test wires and the second test wire are disposed on the second gate insulating layer.

In an embodiment, the display device may include an inter-insulating layer disposed on the second gate insulating layer, where the inter-insulating layer covers the plurality of first test wires and the second test wire.

In an embodiment, the display device may further include a first gate insulating layer disposed on the substrate, a gate electrode disposed on the first gate insulating layer, and a second gate insulating layer disposed on the gate electrode and the first gate insulating layer, where the plurality of first test wires and the second test wire are disposed between the first gate insulating layer and the second gate insulating layer.

In an embodiment, the plurality of first test wires and the second test wire may include a same material as that of the gate electrode.

In an embodiment, the display device may further include a driving circuit chip disposed on the peripheral area and configured to supply a signal for driving the light-emitting element, and a pad portion including a terminal electrically connected to the driving circuit chip, a first inspection terminal connected to the plurality of first test wires, and a second inspection terminal connected to the second test wire.

In an embodiment, the display device may further include a printed circuit board (“PCB”) attached to an end of the substrate, where the PCB is electrically connected to the terminal electrically connected to the driving circuit chip, the first inspection terminal, and the second inspection terminal.

In an embodiment, a display device may include a display panel, an optical layer disposed on a front surface of the display panel, a cover window disposed on the optical layer, a protection plate disposed on a rear surface of the display panel, and a static electricity prevention layer covering a side surface of the display panel, a side surface of the optical layer, and a side surface of the protection plate, where the display panel may include a substrate including a display area and a peripheral area disposed outside the display area, a light-emitting element disposed on the display area of the substrate, and a static electricity test wire including a plurality of first test wires disposed on the peripheral area and connected to the static electricity prevention layer, respectively, and a second test wire electrically connected to the plurality of first test wires.

In an embodiment, ends of the plurality of first test wires may be aligned with an end of the substrate.

In an embodiment, the display panel may further include a first gate insulating layer disposed on the substrate, a gate electrode disposed on the first gate insulating layer, and a second gate insulating layer disposed on the gate electrode and the first gate insulating layer, where the plurality of first test wires and the second test wire are disposed on the second gate insulating layer.

In an embodiment, the display device may include an inter-insulating layer disposed on the second gate insulating layer, where the inter-insulating layer covers the plurality of first test wires and the second test wire.

In an embodiment, the plurality of first test wires may be arranged along a first direction, and the second test wire extends along the first direction.

In an embodiment, the display device may further include a crack test wire surrounding the display area of the substrate, where the second test wire may be disposed outside the crack test wire, and the plurality of first test wires are disposed outside the second test wire.

In an embodiment, the static electricity test wire may be disposed in a same layer as the crack test wire, and may include a same material as that of the crack test wire.

In an embodiment, the display device may include a static electricity test wire disposed on an end of the display panel, such that a plurality of first test wires and a second test wire may form a current path through a static electricity prevention layer, and accordingly, an open defect of the static electricity prevention layer may be easily detected.

### BRIEF DESCRIPTION OF THE DRAWINGS

The above and other embodiments, advantages and features of this disclosure will become more apparent by describing in further detail embodiments thereof with reference to the accompanying drawings, in which:

FIG. 1 is a top plan view schematically showing an embodiment of a display device.

FIG. 2 is a cross-sectional view taken along line A-A′ of FIG. 1.

FIG. 3 is a top plan view schematically showing an embodiment of a display device.

FIG. 4 is an enlarged top plan view of a region Q1 of FIG. 3.

FIG. 5 is a cross-sectional view taken along line B-B′ of FIG. 3.

FIG. 6 is an enlarged cross-sectional view of a region Q2 of FIG. 5.

FIG. 7 is a cross-sectional view taken along line C-C′ of FIG. 3.

FIG. 8 is an enlarged cross-sectional view of a region Q3 of FIG. 7.

FIG. 9 to FIG. 11 are cross-sectional views corresponding to the region Q2 of FIG. 5, showing an embodiment of a static electricity test wire of a display device.

FIG. 12 is a top plan view corresponding to the region Q1 of FIG. 3, showing an embodiment of a static electricity test wire of a display device.

FIG. 13 is a top plan view corresponding to the region Q1 of FIG. 3, showing an embodiment of a display device.

FIG. 14 is a block diagram of an electronic device according to an embodiment.

FIG. 15 shows schematic diagrams of electronic devices according to various embodiments.

### DETAILED DESCRIPTION

Embodiments of the disclosure will be described more fully hereinafter with reference to the accompanying drawings, in which embodiments of the invention are shown. As those skilled in the art would realize, the described embodiments may be modified in various different ways, all without departing from the spirit or scope of the invention.

In order to clearly describe the invention, parts or portions that are irrelevant to the description are omitted, and identical or similar constituent elements throughout the specification are denoted by the same reference numerals.

Further, in the drawings, the size and thickness of each element are arbitrarily illustrated for ease of description, and the disclosure is not necessarily limited to those illustrated in the drawings. In the drawings, the thicknesses of layers, films, panels, regions, areas, etc., are exaggerated for clarity. In the drawings, for ease of description, the thicknesses of some layers and areas are exaggerated.

It will be understood that when an element such as a layer, film, region, area, or substrate is referred to as being “on” or “above” another element, it may be directly on the other element or intervening elements may also be present. In contrast, when an element is referred to as being “directly on” another element, there are no intervening elements present. Further, in the specification, the word “on” or “above” means disposed on or below the object portion, and does not necessarily mean disposed on the upper side of the object portion based on a gravitational direction.

In addition, unless explicitly described to the contrary, the word “comprise” and variations such as “comprises” or “comprising” will be understood to imply the inclusion of stated elements but not the exclusion of any other elements.

Further, throughout the specification, the phrase “in a plan view” or “in a plan view” means viewing a target portion from the top, and the phrase “in a cross-sectional view” or “in a cross-section” means viewing a cross-section formed by vertically cutting a target portion from the side.

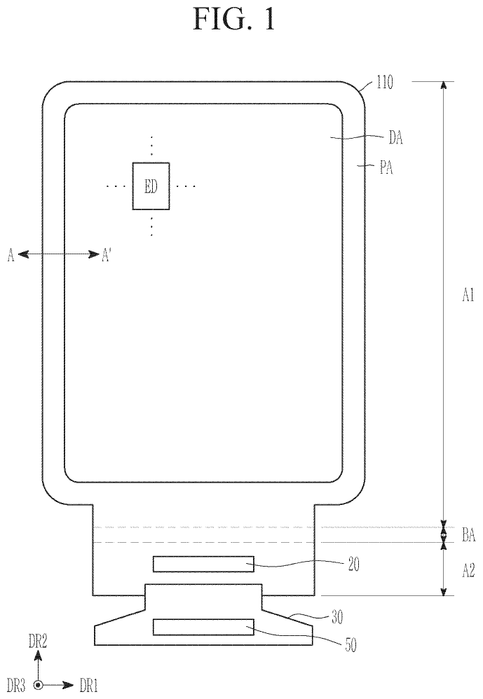

Hereinafter, referring to FIG. 1, a semiconductor device in an embodiment will be described in detail.

Referring to FIG. 1, a display device in an embodiment may include a display area DA and a substrate 110 including a peripheral area PA disposed next (adjacent) to the display area DA, a light-emitting element ED disposed on the display area DA of the substrate 110, and a driver disposed in the peripheral area PA of the substrate 110.

The substrate 110 may be flexible, stretchable, foldable, or bendable, or may include or consist of a rollable material.

The display area DA is a region for displaying a screen, and may be generally quadrangular, e.g., rectangular. In an embodiment, the display area DA may be formed in a quadrangular shape, e.g., rectangular shape including two sides extending in a first direction DR1 and two sides extending in a second direction DR2, and corner portions may be in a round form by being chamfered. However, this may be merely one of embodiments, and the shape of the display area DA may be changed in various ways depending on the purpose or the like of a display device.

A plurality of light-emitting elements ED may be disposed in a predetermined form in the display area DA. In an embodiment, the plurality of light-emitting elements ED may be disposed along row and column directions, for example. However, this may be merely one of embodiments, and the arrangement form of the plurality of light-emitting elements ED may be changed in various ways. Each light-emitting element ED may be applied with a predetermined signal through a plurality of signal lines. The signal lines and the light-emitting element ED may be connected through a transistor. That is, a transistor and signal lines connected to the light-emitting element ED may be disposed in the display area DA. The signal lines may include a scan line, a data line, a driving voltage line, an initialization voltage line, a common voltage line, or the like. These signal lines may extend in one direction and be connected to the plurality of light-emitting elements ED.

The display area DA may further include a touch sensor for detecting the user's contact and/or non-contact touch.

The peripheral area PA may be disposed outside the display area DA, and may be formed to surround the display area DA. The peripheral area PA may include a first region A1 surrounding the display area DA, a second region A2 disposed to be spaced apart from an edge of the first region A1, and a bending region BA disposed between the first region A1 and the second region A2. In an embodiment, the bending region BA may extend from a lower edge of the first region A1, and the second region A2 may extend from the bending region BA, for example. The substrate 110 may be bent in the bending region BA. The bending region BA may be formed in a shape that extends long along the first direction DR1. When the substrate 110 is bent along the bending region BA, the second region A2 may be disposed on a rear surface of the first region A1. That is, when the substrate 110 is in a bent state, the second region A2 and the first region Al may overlap each other.

In the peripheral area PA, a driving circuit unit that generates and transmits a signal for driving a display device in an embodiment, such as a driving circuit chip 20, a printed circuit board (“PCB”) 30, an integrated circuit (“IC”) driving chip 50, a scan driver, or the like, may be disposed.

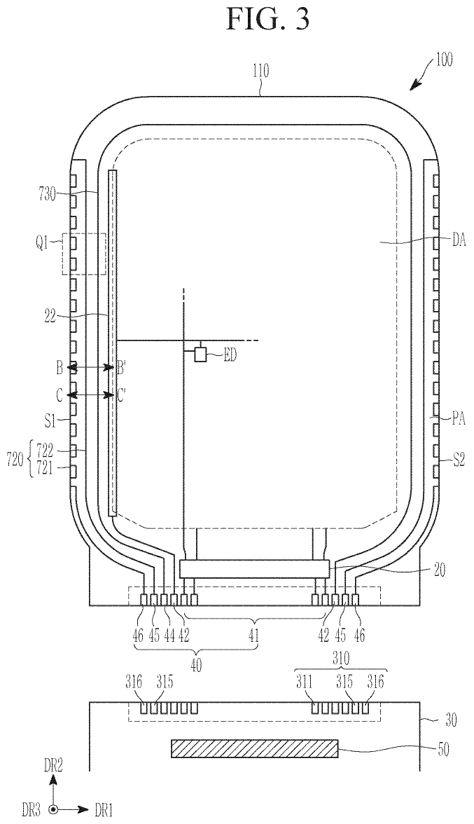

The driving circuit chip 20 and the PCB 30 may be disposed in the second region A2. The driving circuit chip 20 may be connected to the light-emitting element ED disposed in the display area DA through a wire, and may transfer various signals. In an embodiment, the driving circuit chip 20 may be connected to a data signal transfer line to transfer a data signal, for example. In addition, the driving circuit chip 20 may be electrically connected to the IC driving chip 50 and/or the PCB 30 through a pad portion 40 (refer to FIG. 3).

The PCB 30 may be attached to an edge of the substrate 110. In an embodiment, the PCB 30 may be attached to an end portion of the second region A2, for example. The PCB 30 may include or consist of a flexible material, and the IC driving chip 50 for controlling driving of a display device in an embodiment may be disposed therein. The IC driving chip 50 may be electrically connected to the driving circuit chip 20, and supply signals for driving the light-emitting element ED to the driving circuit chip 20. In addition, the IC driving chip 50 may be electrically connected to a scan driver 22 (refer to FIG. 3), and supply signals for driving the light-emitting element ED.

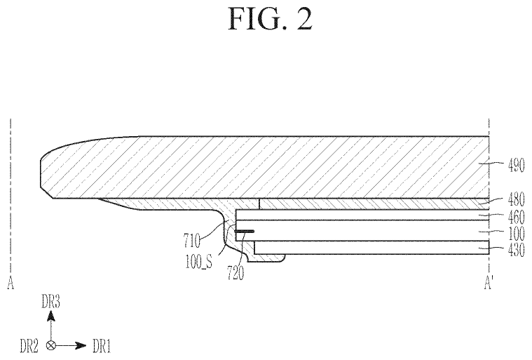

In an embodiment, the peripheral area PA may include a static electricity test wire 720 (refer to FIG. 2). The static electricity test wire 720 (refer to FIG. 2) may be disposed on an edge of the peripheral area PA. The static electricity test wire 720 (refer to FIG. 2) may be a wire for inspection of an open defect of a static electricity prevention layer 710 (refer to FIG. 2) that covers a side surface of a display panel 100.

In an embodiment, the peripheral area PA may further include the scan driver 22 (refer to FIG. 3). The scan driver 22 (refer to FIG. 3) may be disposed in the first region A1, and may be disposed in the first region Al next (adjacent) to a left side edge and/or a right side edge of the display area DA. The scan driver may be connected to the light-emitting element ED through a scan line, and may transmit scan signals. Each of the light-emitting elements ED may be applied with a data signal at predetermined timing according to the scan signal. A signal line for transferring various control signals, a driving voltage, a common voltage, or the like may be further disposed in the peripheral area PA. The signal lines may be connected to the IC driving chip 50, and may receive a predetermined signal from the IC driving chip 50.

Hereinafter, referring to FIG. 2, a cross-sectional shape of a display device in an embodiment will be described in detail.

FIG. 2 is a cross-sectional view taken along line A-A′ of FIG. 1.

Referring to FIG. 2, a display device in an embodiment may include an optical layer 460 and a cover window 490 disposed on a front surface of the display panel 100, an adhesive layer 480 disposed between the optical layer 460 and the cover window 490, a protection plate 430 disposed on a rear surface of the display panel 100, the static electricity prevention layer 710 that covers the side surface of the display panel 100, and the static electricity test wire 720 disposed on an edge of the display panel 100.

The optical layer 460 may be disposed on the front surface of the display panel 100. It may be disposed on an upper surface of the display panel 100. The optical layer 460 may be embedded within the display panel 100. The optical layer 460 may include a phase delay layer, a polarization layer, or the like. The optical layer 460 may include or consist of a single layer, and may be formed in multiple layers in which various layers are stacked.

The cover window 490 may be disposed on the optical layer 460. It may be disposed on the front surface of the display panel 100. The cover window 490 may cover an entirety of the display panel 100. The cover window 490 may overlap with the entirety of the display panel 100 in a third direction DR3. A width of the cover window 490 along the first direction DR1 may be greater than a width of the display panel 100 along the first direction DR1. The cover window 490 may serve to protect the display panel 100 from external interference.

The adhesive layer 480 may be disposed between the optical layer 460 and the cover window 490. The adhesive layer 480 may include or consist of an optically clear adhesive (“OCA”), an optically clear resin (“OCR”), a pressure-sensitive adhesive (“PSA”), or the like. The adhesive layer 480 may serve to bond between the display panel 100 and the cover window 490.

The protection plate 430 may be disposed on the rear surface of the display panel 100. The protection plate 430 may be disposed on a lower surface of the display panel 100. A protection film and/or adhesive layer may be further disposed between the display panel 100 and the protection plate 430. The protection plate 430 may serve to help the display panel 100 to maintain a constant shape. In addition, the protection plate 430 may include or consist of a metallic material such as copper, and perform a heat dissipation function. The protection plate 430 may include or consist of a material such as graphite, PET, or the like.

In an embodiment, the static electricity prevention layer 710 may cover the edge of the display panel 100. The static electricity prevention layer 710 may cover a side surface of the protection plate 430, the side surface of the display panel 100, a side surface of the optical layer 460, and a side surface of the adhesive layer 480. In addition, the static electricity prevention layer 710 may be disposed on a lower surface of the cover window 490 and a lower surface of the protection plate 430. The static electricity prevention layer 710 may be formed by coating a conductive polymer compound on the lower surface of the cover window 490, the lower surface and the side surface of the protection plate 430, the side surface of the display panel 100, the side surface of the optical layer 460, and the side surface of the adhesive layer 480. In an embodiment, the static electricity prevention layer 710 may be a coating layer of the conductive polymer compound, for example. When static electricity occurs in the cover window 490, the static electricity prevention layer 710 may serve to discharge the static electricity through the protection plate 430. In an embodiment, the static electricity prevention layer 710 may form a current path from the cover window 490 to the ground terminal of the protection plate 430, and thereby weaken the electric field between the cover window 490 and the protection plate 430, for example. Through this, an image quality defect, or the like, due to the static electricity of a display device in an embodiment may be improved.

The static electricity test wire 720 may be disposed on a first end of the display panel 100. In an embodiment, the static electricity test wire 720 may be disposed in first side and second side end portions of the display panel 100 along the first direction DR1, respectively, for example. However, it is not limited thereto, and the static electricity test wire 720 may be disposed on first side or second side end portions along the first direction DR1.

An end point of the static electricity test wire 720 may be aligned with the side surface of the display panel 100. In an embodiment, the end point of the static electricity test wire 720 may be aligned with a side surface 100_S of the display panel 100, for example. Accordingly, the static electricity test wire 720 may contact the static electricity prevention layer 710. In an embodiment, the static electricity test wire 720 may be a wire for inspection of an open defect of the static electricity prevention layer 710. Here, the term “open defect of the static electricity prevention layer 710” refers to a case where, during the process of forming the static electricity prevention layer 710, portions of the display panel 100 are not covered by the static electricity prevention layer 710. In this case, the current path formed from the cover window 490 to the ground terminal of the protection plate 430 may be weakened, and thereby the electrostatic charge of the cover window 490 may be caused to flow into the display panel 100, potentially generating image quality defects. Detailed description for the static electricity test wire 720 will be hereinafter described with reference to FIG. 3.

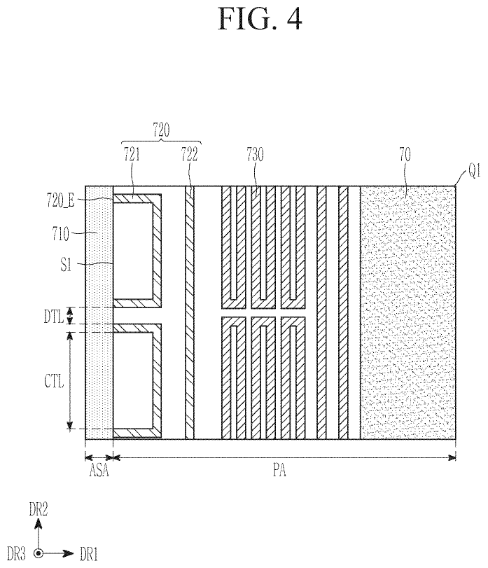

Hereinafter, referring to FIG. 3 and FIG. 4, the static electricity test wire 720 of a display device in an embodiment will be described in detail.

FIG. 3 is a top plan view schematically showing an embodiment of a display device. FIG. 4 is an enlarged top plan view of a region Q1 of FIG. 3.

Referring to FIG. 3 and FIG. 4, a display device in an embodiment may include the driving circuit unit, and the driving circuit unit may include a plurality of driver and signal wires. In an embodiment, the driving circuit unit may include the scan driver 22, the driving circuit chip 20, signal transmission wires and the pad portion 40 connected to those, or the like, for example. At least a portion of the driving circuit unit may be disposed in the display area DA, and a remaining part may be disposed in the peripheral area PA.

The scan driver 22 may generate a scan signal and transmit it to a pixel circuit unit electrically connected to the light-emitting element ED through a scan line. Depending on an embodiment, the scan driver 22 may be disposed in a left side of the display area DA, but is not limited thereto. In another embodiment, the scan driver 22 may be disposed on opposite sides of the substrate 110.

The driving circuit chip 20 may disposed on the peripheral area PA, and may generate a data signal and transmit it to the pixel circuit unit connected to the light-emitting element ED through a data line. The driving circuit chip 20 may be disposed on a first side of the display panel 100, and for example, may be disposed between the pad portion 40 and the display area DA.

The pad portion 40 may be disposed on a first side end portion of the substrate 110, and may include a plurality of terminals 41, 42, 44, 45, and 46. In an embodiment, the pad portion 40 of the display panel 100 may include the terminal 41 connected to the driving circuit chip 20, a terminal 42 connected to the scan driver 22, a terminal 44 connected to a crack test wire 730, and detection terminals 45 and 46 connected to the static electricity test wire 720, for example. The pad portion 40 is exposed by not being covered by the insulating layer, and may be electrically connected to the PCB 30. The pad portion 40 may be connected to a pad portion 310 of the PCB 30.

The PCB 30 may transfer the signal or power of the IC driving chip 50 to the pad portion 40. The pad portion 310 of the PCB 30 may include a plurality of terminals 311, 315, and 316 corresponding to the plurality of terminals 41, 42, 44, 45, and 46 of the pad portion 40 of the display panel 100. In an embodiment, the pad portion 310 of the PCB 30 may include the terminal 311 connected to the terminal 41 connected to the driving circuit chip 20, and detection terminals 315 and 316 connected to the detection terminals 45 and 46 of the display panel 100, for example. Accordingly, the PCB 30 may be electrically connected to the terminal 41 and the detection terminals 45 and 46 connected to the driving circuit chip 20.

The IC driving chip 50 may change a plurality of video signals that are transferred from the outside to a plurality of image data signals, and may transfer the changed signal to the driving circuit chip 20 through the terminal 41. In addition, the IC driving chip 50 may receive a vertical synchronization signal, a horizontal synchronizing signal, and a clock signal, generate a control signal for controlling driving of the scan driver 22, and transfer it to the scan driver 22 through the terminal 42. The IC driving chip 50 may transfer a crack detection signal for detecting a crack of the display device to the crack test wire 730 through the terminal 44. The IC driving chip 50 may transfer a static electricity test signal to the static electricity test wire 720 through the detection terminals 45 and 46. In addition, the IC driving chip 50 may transfer a driving voltage ELVDD to a driving voltage supply line through terminals, and may transfer a common voltage ELVSS to a common voltage supply line.

A display device in an embodiment may further include the crack test wire 730. The crack test wire 730 may be disposed on the peripheral area PA of the substrate 110. The crack test wire 730 may have a shape that surrounds the display area DA. The crack test wire 730 may serve to detect a case that a crack has occurred in the display panel 100.

The static electricity test wire 720 may be disposed on the peripheral area PA of the substrate 110. The static electricity test wire 720 may be disposed on at least one side of the substrate 110. In an embodiment, the static electricity test wire 720 may be disposed on a first side and a second side of the substrate 110 along the first direction DR1, for example, but is not limited thereto. In an embodiment, the static electricity test wire 720 may be disposed on the edge of the substrate 110. The static electricity test wire 720 may be disposed next (adjacent) to a first side surface S1 of the substrate 110 and a second side surface S2 facing the first side surface S1 in the first direction DR1. The static electricity test wire 720 may be disposed outside the crack test wire 730. That is, the crack test wire 730 may be disposed between the static electricity test wire 720 and the display area DA.

The static electricity test wire 720 may be connected to inspection terminals 45 and 46 of the pad portion 40. Each of the inspection terminals 45 and 46 may be connected to the pad portion 310 of the PCB 30, and electrically connected to the IC driving chip 50 or controller. In an embodiment, a first inspection terminal 45 connected to the static electricity test wire 720 may be connected to a first inspection terminal 315 of the PCB 30, and a second inspection terminal 46 connected to the static electricity test wire 720 may be connected to a second inspection terminal 316 of the PCB 30, for example.

Referring further to FIG. 4, the static electricity test wire 720 may include a plurality of first test wires 721 arranged to be spaced apart from each other and a second test wire 722 electrically connected to the plurality of first test wires 721.

The plurality of first test wires 721 may be arranged to be spaced apart along the second direction DR2. In an embodiment, the plurality of first test wires 721 may be repeatedly arranged on an end of the substrate 110, for example. The plurality of first test wires 721 may be arranged along an elongation direction (e.g., the second direction DR2) of the first side surface S1 and the second side surface S2 of the substrate 110. The plurality of first test wires 721 may be disposed on the edge of the substrate 110. The plurality of first test wires 721 may be disposed outside the second test wire 722. The plurality of first test wires 721 may be disposed next (adjacent) to the first side surface S1 of the substrate 110 and the second side surface S2 facing the first side surface S1 in the first direction DR1. A first end 720_E of the plurality of first test wires 721 may be aligned with a side surface of the substrate 110. In an embodiment, as shown in FIG. 4, the first end 720_E of the plurality of first test wires 721 may be aligned with the first side surface S1 of the substrate 110, for example. The first end 720_E of the plurality of first test wires 721 and the side surface of the substrate 110 may contact the static electricity prevention layer 710. Each of the plurality of first test wires 721 may be connected to the static electricity prevention layer 710.

Accordingly, each of the plurality of first test wires 721 may be electrically connected to the static electricity prevention layer 710. In an embodiment, each of the plurality of first test wires 721 may include horizontal portions extending generally in the first direction DR1 and contacting the static electricity prevention layer 710 and an extension portion extending generally in the second direction DR2 and connecting between the horizontal portions, for example. At this time, first ends of the horizontal portions may be aligned with the side surface of the substrate 110. The horizontal portions of each of the plurality of first test wires 721 may be electrically connected to the static electricity prevention layer 710, and accordingly, between the plurality of first test wires 721 next (adjacent) to each other in the second direction DR2 may be electrically connected to each other through the static electricity prevention layer 710. Hereinafter, for convenience of description, a region between the plurality of first test wires 721 next (adjacent) to each other in the second direction DR2 may be also referred to as an inspection region DTL, and a region between the horizontal portions of each of the plurality of first test wires 721 may be also referred to as a dummy region CTL. That is, in an embodiment, in the inspection region DTL, the plurality of first test wires 721 may be electrically connected to each other through the static electricity prevention layer 710.

Accordingly, the plurality of first test wires 721 may have an open or short circuit state depending on whether there is an open defect of the static electricity prevention layer 710 in the inspection region DTL. In an embodiment, when an open defect of the static electricity prevention layer 710 has occurred in the inspection region DTL, a space between the plurality of first test wires 721 next (adjacent) to each other in the second direction DR2 may be electrically open, for example. When the static electricity prevention layer 710 is formed in the inspection region DTL, the plurality of first test wires 721 next (adjacent) to each other in the second direction DR2 may be electrically connected to each other. Therefore, the plurality of first test wires 721 may have an open state or a short circuit state depending on whether there is an open defect of the static electricity prevention layer 710 in the inspection region DTL. A length of the inspection region DTL along the second direction DR2 may be smaller than or equal to a length of the dummy region CTL along the second direction DR2. In this range, while preventing the resistance value due to the static electricity prevention layer 710 from increasing, the inspection region DTL may be easily secured.

The second test wire 722 may extend long generally along the second direction DR2 in a plan view. The second test wire 722 may be spaced apart from the plurality of first test wires 721. In an embodiment, the second test wire 722 may be spaced apart from the plurality of first test wires 721 in the first direction DR1, for example, but is not limited thereto. In an embodiment, the second test wire 722 may be disposed between the crack test wire 730 and the plurality of first test wires 721. That is, the second test wire 722 may be disposed outside the crack test wire 730. A width of the second test wire 722 along the first direction DR1 may be substantially the same as a width of the plurality of first test wires 721, but is not limited thereto, and they may be different. The second test wire 722 may be electrically connected to the plurality of first test wires 721 through the static electricity prevention layer 710. However, it is not limited thereto, and the second test wire 722 may be directly connected to at least one among the plurality of first test wires 721.

In summary, the plurality of first test wires 721 and the second test wire 722 of a display device in an embodiment may form a current path through the static electricity prevention layer 710, and the current path may have an open or short circuit state depending on whether there is an open defect of the static electricity prevention layer 710 in the inspection region DTL. Accordingly, the IC driving chip 50 and/or controller may transfer a static electricity test signal to the static electricity test wire 720 through the detection terminals 45 and 46, and thereby detect whether there is an open defect of the static electricity prevention layer 710.

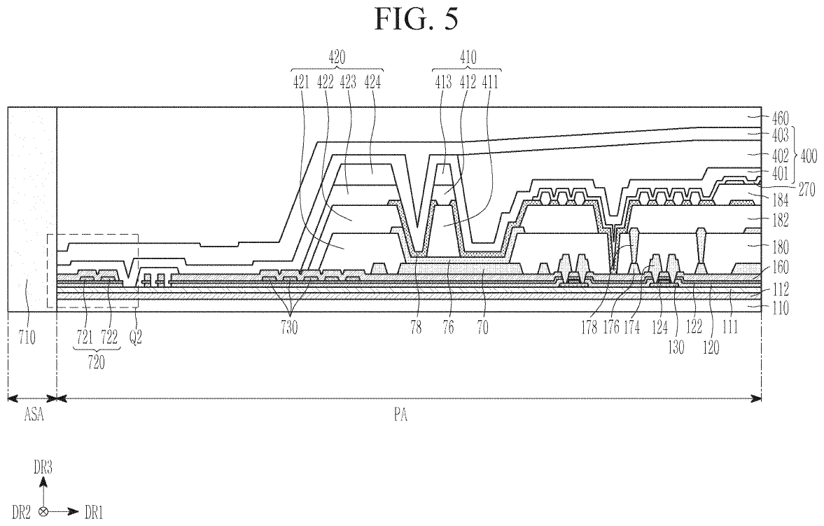

Hereinafter, referring to FIG. 5 to FIG. 8, a cross-sectional shape of a peripheral area of a display device in an embodiment will be described in detail.

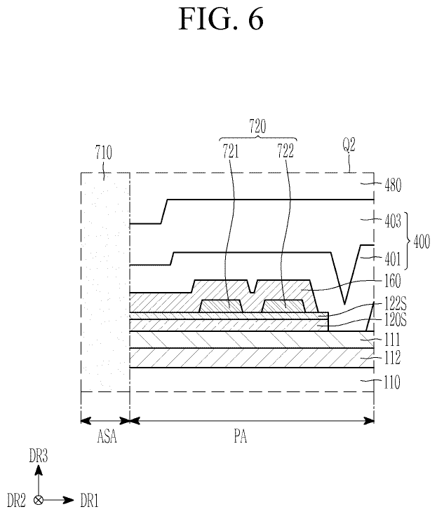

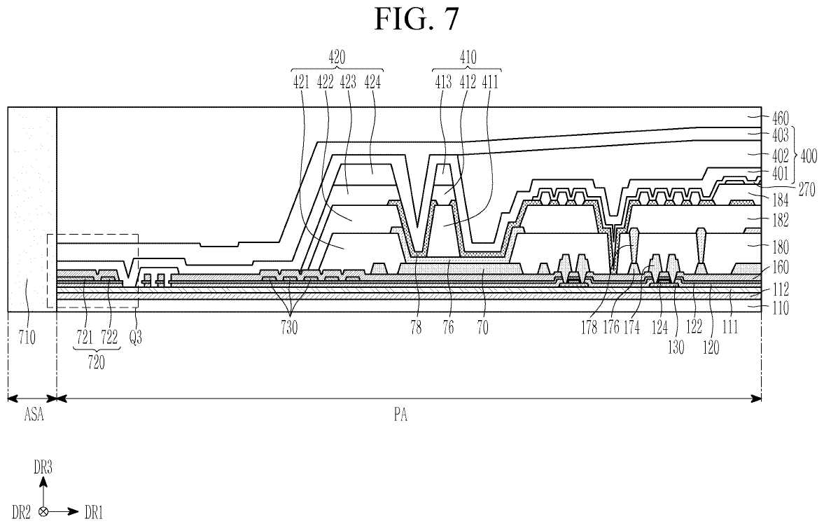

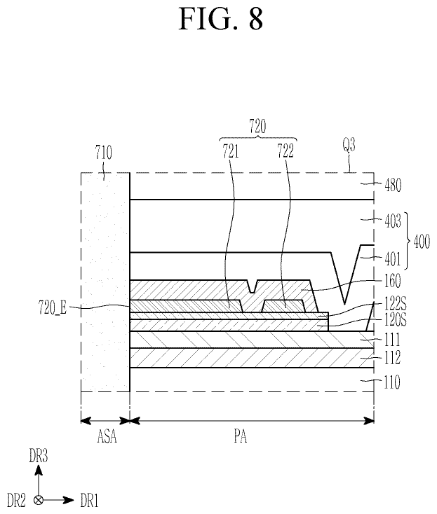

FIG. 5 is a cross-sectional view taken along line B-B′ of FIG. 3. FIG. 6 is an enlarged cross-sectional view of a region Q2 of FIG. 5. FIG. 7 is a cross-sectional view taken along line C-C′ of FIG. 3. FIG. 8 is an enlarged cross-sectional view of a region Q3 of FIG. 7. In FIG. 5 to FIG. 8, the peripheral area PA of the substrate 110 is shown but the display area is not shown. In addition, for better understanding and ease of description, in FIG. 5 to FIG. 8, at least a portion of the display panel and the optical layer 460 is shown, and the adhesive layer 480, the cover window 490, and the protection plate 430 of FIG. 2 are not shown.

First, referring to FIG. 5, a display device in an embodiment may include the substrate 110, a buffer layer 111, a barrier layer 112, a semiconductor layer 130, a first gate insulating layer 120, a gate electrode 124, a second gate insulating layer 122, an inter-insulating layer 160, the crack test wire 730, the static electricity test wire 720, a source/drain electrode 174, a common voltage supply line 70, a first passivation layer 180, connection electrodes 176 and 178, a second passivation layer 182, a third passivation layer 184, an extension electrode 78, a common electrode 270, and an encapsulation layer 400.

The substrate 110 may include at least one of polystyrene, polyvinyl alcohol, poly(methyl methacrylate), polyethersulfone, polyacrylate, polyetherimide, polyethylene naphthalate, polyethylene terephthalate, polyphenylene sulfide, polyarylate, polyimide, polycarbonate, cellulose triacetate, and cellulose acetate propionate. The substrate 110 may be a rigid substrate, or a flexible substrate that is bendable, foldable, or rollable. The substrate 110 may be single-layered or multiple-layered. The substrate 110 may be a substrate in which at least one base layer and at least one inorganic layer, which include polymer resins sequentially stacked, are alternately stacked.

On the substrate 110, a buffer layer 111 may be further disposed to flatten the surface of the substrate 110 and block the penetration of impurities. The buffer layer 111 may include an inorganic material, and for example, may include an inorganic insulating material such as a silicon nitride (SiNx), a silicon oxide (SiOx), a silicon oxynitride (SiOxNy), or the like. The buffer layer 111 may have a single-layer or multi-layer structure of the above materials. The barrier layer 112 may be further disposed on the substrate 110. The barrier layer 112 may be disposed between the substrate 110 and the buffer layer 111. The barrier layer 112 may include an inorganic insulating material such as a silicon nitride (SiNx), a silicon oxide (SiOx), a silicon oxynitride (SiOxNy), or the like. The barrier layer 112 may be a single-layer or multi-layer structure of the material.

The semiconductor layer 130 may be disposed on the buffer layer 111. The semiconductor layer 130 may include one of amorphous silicon, polycrystalline silicon, and an oxide semiconductor. In an embodiment, the semiconductor layer 130 may include low-temperature polysilicon (“LTPS”) or may include an oxide semiconductor material including or consisting of at least one of zinc (Zn), indium (In), gallium (Ga), tin (Sn), and combination thereof, for example. In an embodiment, the semiconductor layer 130 may include indium gallium zinc oxide (“IGZO”), for example. The semiconductor layer 130 may include a channel region, a source region, and a drain region, which are distinguished based on impurity doping. A source region and a drain region may be disposed on opposite sides of a channel region of the semiconductor layer 130, respectively. The source region and the drain region may exhibit conductive characteristics corresponding to a conductor.

The first gate insulating layer 120 may be disposed on the semiconductor layer 130. The first gate insulating layer 120 may cover the semiconductor layer 130 and the substrate 110. The first gate insulating layer 120 may include an inorganic insulating material such as a silicon nitride (SiNx), a silicon oxide (SiOx), a silicon oxynitride (SiOxNy), or the like. The first gate insulating layer 120 may be a single-layer or multi-layer structure of the material.

The gate electrode 124 may be disposed on the first gate insulating layer 120. The gate electrode 124 may include a metal such as copper (Cu), molybdenum (Mo), aluminum (Al), silver (Ag), chromium (Cr), tantalum (Ta), titanium (Ti), or the like, or a metal alloy. The gate electrode 124 may be configured as a single layer or multiple layers. After forming the gate electrode 124, a doping process or plasma treatment may be performed. The portion of the semiconductor layer 130 covered by the gate electrode 124 remains undoped or untreated by plasma, and in contrast, the portion of the semiconductor layer 130 not covered by the gate electrode 124 may undergo doping or plasma treatment to exhibit characteristics similar to a conductor. Within the semiconductor layer 130, a region overlapping with the gate electrode 124 in a plan view may become a channel region.

The second gate insulating layer 122 and the inter-insulating layer 160 may be disposed on the gate electrode 124. The second gate insulating layer 122 and the inter-insulating layer 160 may cover the gate electrode 124 and the first gate insulating layer 120. The second gate insulating layer 122 and the inter-insulating layer 160 may include an inorganic insulating material such as a silicon nitride (SiNx), a silicon oxide (SiOx), a silicon oxynitride (SiOxNy), or the like. The second gate insulating layer 122 and the inter-insulating layer 160 may be a single-layer or multi-layer structure of the material.

The crack test wire 730 may be disposed on the second gate insulating layer 122. The crack test wire 730 may be disposed on the second gate insulating layer 122. The crack test wire 730 may be disposed between the second gate insulating layer 122 and the inter-insulating layer 160. The crack test wire 730 may be disposed outside the common voltage supply line 70. The crack test wire 730 may be disposed between the static electricity test wire 720 and the common voltage supply line 70. At least a portion of the crack test wire 730 may overlap with dams 410 and 420 in the third direction DR3, but is not limited thereto, and may be disposed outside the dams 410 and 420. The crack test wire 730 may include various conductive materials.

Referring further to FIG. 6, a display device in an embodiment may further include a first sub-gate insulating layer 120S and a second sub-gate insulating layer 122S disposed on the buffer layer 111.

The first sub-gate insulating layer 120S may be spaced apart from the first gate insulating layer 120. In an embodiment, the first sub-gate insulating layer 120S may be spaced apart from the first gate insulating layer 120 in the first direction DR1, for example. Here, the first sub-gate insulating layer 120S may mean a portion of the first gate insulating layer 120 that is patterned in order to form the static electricity test wire 720.

That is, the first sub-gate insulating layer 120S may be a portion of the first gate insulating layer 120 that is disposed on one end of the substrate 110, and disposed on a lower surface of the static electricity test wire 720. That is, the first sub-gate insulating layer 120S may be configured as a portion of the first gate insulating layer 120. The first sub-gate insulating layer 120S may be separated from the first gate insulating layer 120 by a trench disposed on a first side of the first gate insulating layer 120. A first end of the first sub-gate insulating layer 120S may be aligned with one end of the substrate 110. The first end of the first sub-gate insulating layer 120S may contact the static electricity prevention layer 710 to be described later. A second end of the first sub-gate insulating layer 120S may contact the encapsulation layer 400 to be described later. The first sub-gate insulating layer 120S may be disposed in the same layer as the first gate insulating layer 120, and may include the same material as that of the first gate insulating layer 120.

The second sub-gate insulating layer 122S may be disposed on the first sub-gate insulating layer 120S. The second sub-gate insulating layer 122S may be spaced apart from the second gate insulating layer 122. In an embodiment, the second sub-gate insulating layer 122S may be spaced apart from the second gate insulating layer 122 in the first direction DR1, for example. Here, the second sub-gate insulating layer 122S may mean a portion of the second gate insulating layer 122 that is patterned in order to form the static electricity test wire 720. The second sub-gate insulating layer 122S may be a portion of the second gate insulating layer 122 that is disposed on one end of the substrate 110, and disposed on the lower surface of the static electricity test wire 720. The second sub-gate insulating layer 122S may be separated from the second gate insulating layer 122 by a trench disposed on a first side of the second gate insulating layer 122. A first end of the second sub-gate insulating layer 122S may be aligned with one end of the substrate 110. The first end of the second sub-gate insulating layer 122S may contact the static electricity prevention layer 710 to be described later. A second end of the second sub-gate insulating layer 122S may contact the encapsulation layer 400 to be described later. The second sub-gate insulating layer 122S may be disposed in the same layer as the second gate insulating layer 122, and may include the same material as that of the second gate insulating layer 122.

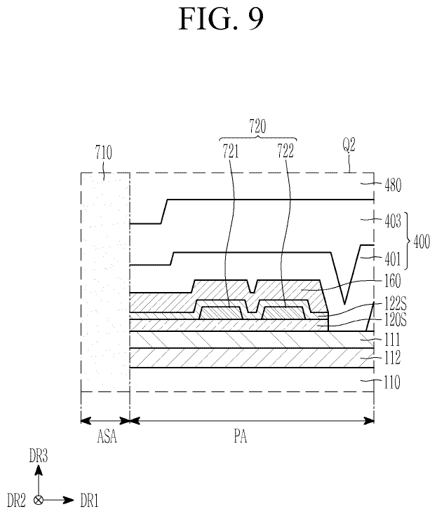

In an embodiment, the static electricity test wire 720 may be disposed on the first sub-gate insulating layer 120S and the second sub-gate insulating layer 122S. The static electricity test wire 720 may be disposed between the second sub-gate insulating layer 122S and the inter-insulating layer 160. Here, the second sub-gate insulating layer 122S may configure a portion of the second gate insulating layer 122. The static electricity test wire 720 may be covered by the inter-insulating layer 160. In an embodiment, a side surface and an upper surface of the first test wire 721 and a side surface and an upper surface of the second test wire 722 may be covered by the inter-insulating layer 160, for example. The plurality of first test wires 721 may be disposed in the same layer as the second test wire 722, and may include the same material as that of the second test wire 722. The static electricity test wire 720 may be disposed in the same layer as the crack test wire 730, and may include the same material as that of the crack test wire 730. However, it is not limited thereto, and in another embodiment, the static electricity test wire 720 may be disposed in the same layer as the gate electrode 124, for example. Detailed description on the above will be provided later with reference to FIG. 9.

In an embodiment, a first end of the static electricity test wire 720 may be aligned with one end of the substrate 110. In an embodiment, as shown in FIG. 7 and FIG. 8, the first end 720_E of the first test wire 721 may be aligned with the end of the substrate 110, for example. The first end 720_E of the first test wire 721 may be aligned with a side surface of the first sub-gate insulating layer 120S and a side surface of the second sub-gate insulating layer 122S. The first end 720_E of the first test wire 721 may contact the static electricity prevention layer 710. A second end of the first test wire 721 may contact the inter-insulating layer 160.

The static electricity test wire 720 may be disposed on an outer side of the crack test wire 730 and the common voltage supply line 70. The static electricity test wire 720 may be disposed outside the dams 410 and 420. Specifically, the second test wire 722 may be disposed outside the crack test wire 730, and the plurality of first test wires 721 may be disposed outside the second test wire 722. That is, the second test wire 722 may be disposed between the plurality of first test wires 721 and the crack test wire 730. The source/drain electrode 174 may be disposed on the inter-insulating layer 160. The source/drain electrode 174 may be connected to the source region and the drain region of the semiconductor layer 130 through openings defined in the inter-insulating layer 160, the second gate insulating layer 122, and the first gate insulating layer 120, respectively. The source/drain electrode 174 may include a metal such as aluminum (Al), copper (Cu), silver (Ag), gold (Au), platinum (Pt), palladium (Pd), nickel (Ni), molybdenum (Mo), tungsten (W), titanium (Ti), chromium (Cr), tantalum (Ta), or the like, or a metal alloy. The source/drain electrode 174 may be configured as a single layer or multiple layers. The source/drain electrode 174 in an embodiment may be configured as triple layers including an upper layer, an intermediate layer, and a lower layer, where the upper layer and the lower layer may include titanium (Ti), and the intermediate layer may include aluminum (Al).

The semiconductor layer 130, the gate electrode 124, the source/drain electrode 174 described above may form one transistor. Depending on an embodiment, the transistor may only include the source region and the drain region of the semiconductor layer 130 instead of the source/drain electrode 174. In an embodiment, each light-emitting element ED (refer to FIG. 3) may be connected to at least one transistor. In an embodiment, one light-emitting element ED (refer to FIG. 3) may be connected to a switching transistor and a driving transistor, for example. In an alternative embodiment, one light-emitting element ED (refer to FIG. 3) may be connected to three or more transistors.

The common voltage supply line 70 may be disposed on the inter-insulating layer 160. The common voltage supply line 70 may transfer the common voltage ELVSS. The common voltage supply line 70 may be disposed on the peripheral area PA. The common voltage supply line 70 may be disposed closer to the edge of the substrate 110 than the transistor including the semiconductor layer 130.

The first passivation layer 180 may be disposed on the common voltage supply line 70 and the source/drain electrode 174. The first passivation layer 180 may cover the source/drain electrode 174 and the inter-insulating layer 160. The first passivation layer 180, which is to planarize the surface of the substrate 110 provided with the transistor, may be an organic insulator, and may include one or more material selected from the group including or consisting of polyimide, polyamide, acryl resin, benzocyclobutene, and phenol resin.

The connection electrodes 176 and 178 may penetrate the first passivation layer 180. The connection electrodes 176 and 178 may be an electrode that connects the transistor and the light-emitting element ED (refer to FIG. 3). The connection electrodes 176 and 178 may include a conductive material, and may be formed in a single layer or multiple layers. In an embodiment, the first passivation layer 180 may include a via hole exposing at least a portion of the source/drain electrode 174. The connection electrodes 176 and 178 may be physically and electrically connected to the source/drain electrode 174 through a via hole of the first passivation layer 180.

The second passivation layer 182 may be disposed on the first passivation layer 180. The second passivation layer 182 may cover the connection electrodes 176 and 178 and the first passivation layer 180. The third passivation layer 184 may be disposed on the second passivation layer 182. The second passivation layer 182 and the third passivation layer 184 may be an organic insulator, and may include one or more material selected from the group including or consisting of polyimide, polyamide, acryl resin, benzocyclobutene, and phenol resin.

The extension electrode 78 may be disposed on the second passivation layer 182. An opening overlapping with the extension electrode 78 and a connection electrode 76 may be formed in the second passivation layer 182 and the first passivation layer 180. The extension electrode 78 may be connected to the connection electrode 76 through an opening. A plurality of openings may be defined in the extension electrode 78. The opening of the extension electrode 78 may form a discharge passage of gas emerging from a layer including or consisting of organic materials during the manufacturing process, thereby reducing its impact on other elements.

The common electrode 270 may be disposed on the third passivation layer 184. The common electrode 270 may also be also referred to as a cathode, and may be formed as a transparent conductive layer including or consisting of indium tin oxide (“ITO”), indium zinc oxide (“IZO”), indium gallium zinc oxide (“IGZO”), and indium tin zinc oxide (“ITZO”). In addition, the common electrode 270 may have a translucent characteristic. In an embodiment, the display area may include, e.g., a pixel electrode disposed on the second passivation layer 182, a light-emitting layer disposed on the pixel electrode. The pixel electrode and the light-emitting layer may configure the light-emitting element ED (refer to FIG. 3) together with the common electrode 270. At this time, the pixel electrode may be an anode, and the common electrode 270 may be a cathode. However, it is not limited thereto, and depending on the driving method of the display device, the anode and the cathode may be formed oppositely. In addition, the display area may further include a pixel definition layer, a spacer, or the like, disposed on the pixel electrode.

A display device in an embodiment may further include the dams 410 and 420 disposed on the substrate 110. The dams 410 and 420 may be disposed on the peripheral area PA of the substrate 110. The dams 410 and 420 may include a first dam 410 and a second dam 420. However, this may be merely one of embodiments, and the number of dams may be appropriately changed depending on cases.

The first dam 410 may include a first layer 411, a second layer 412, and a third layer 413. The second layer 412 may be disposed on the first layer 411 of the first dam 410, and the third layer 413 may be disposed on the second layer 412. The first layer 411 of the first dam 410 may be disposed in the same layer as the second passivation layer 182, and may include the same material as that of the second passivation layer 182. The second layer 412 of the first dam 410 may be disposed in the same layer as the third passivation layer 184, and may include the same material as that of the third passivation layer 184.

The second dam 420 may include a first layer 421, a second layer 422, a third layer 423, and a fourth layer 424. The second layer 422, the third layer 423, and the fourth layer 424 may be sequentially disposed on the first layer 421 of the second dam 420. The first layer 421 of the second dam 420 may be disposed in the same layer as the first passivation layer 180, and may include the same material as that of the first passivation layer 180. The second layer 422 of the second dam 420 may be disposed in the same layer as the second passivation layer 182, and may include the same material as that of the second passivation layer 182. The third layer 423 of the second dam 420 may be disposed in the same layer as the third passivation layer 184, and may include the same material as that of the third passivation layer 184.

In the above, although it has been described that the first dam 410 is formed in a triple layer structure, the second dam 420 is formed in a quadruple-layer structure, it is not limited thereto, and it may be changed in various ways. The number of layers forming the dams 410 and 420 may be smaller or may be larger.

The encapsulation layer 400 may be disposed on the common electrode 270 and the dams 410 and 420. The encapsulation layer 400 may include at least one inorganic layer and at least one organic layer. In the illustrated embodiment, the encapsulation layer 400 may include a first inorganic encapsulation layer 401, an organic encapsulation layer 402, and a second inorganic encapsulation layer 403. However, this may be merely one of embodiments, and the number of inorganic layers and organic layers forming the encapsulation layer 400 may be changed in various ways.

The first inorganic encapsulation layer 401, the organic encapsulation layer 402 and the second inorganic encapsulation layer 403 may be disposed in at least a portion of the peripheral area PA. Depending on an embodiment, the organic encapsulation layer 402 may formed with a center of the display area DA (refer to FIG. 3), and the first inorganic encapsulation layer 401 and the second inorganic encapsulation layer 403 may be formed up to the peripheral area PA. The encapsulation layer 400 is designed to protect the light-emitting element ED (refer to FIG. 3) from moisture or oxygen that may infiltrate from the outside, and an end portion of the first inorganic encapsulation layer 401 and the second inorganic encapsulation layer 403 may be in direct contact.

The first inorganic encapsulation layer 401 and the second inorganic encapsulation layer 403 may be disposed overall in the display area DA (refer to FIG. 3) and the peripheral area PA. A side surface of the first inorganic encapsulation layer 401 and the second inorganic encapsulation layer 403 may be aligned with the side surface of the substrate 110. The organic encapsulation layer 402 may be disposed in a portion of the peripheral area PA. An end portion of the organic encapsulation layer 402 may reach the first dam 410. The organic encapsulation layer 402 may overlap with a portion of the first dam 410 in the third direction DR3. The first dam 410 may control spreading of the material for forming the organic encapsulation layer 402 during the process of forming the organic encapsulation layer 402. The organic encapsulation layer 402 may have a shape that fills a space between an end portion of the display area DA (refer to FIG. 3) and the first dam 410. In a portion where the organic encapsulation layer 402 is disposed, the organic encapsulation layer 402 may be disposed between the first inorganic encapsulation layer 401 and the second inorganic encapsulation layer 403. In a portion where the organic encapsulation layer 402 is not disposed, the second inorganic encapsulation layer 403 may be disposed directly on the first inorganic encapsulation layer 401.

The optical layer 460 may be disposed on the encapsulation layer 400. The optical layer 460 may be disposed overall on the encapsulation layer 400. An end portion of the optical layer 460 may be aligned with the end portion of the first inorganic encapsulation layer 401 and the second inorganic encapsulation layer 403.

The static electricity prevention layer 710 may be disposed on the side surface of the substrate 110 and the side surface of the optical layer 460. The static electricity prevention layer 710 may be disposed in a coating region ASA disposed outside the peripheral area PA. The static electricity prevention layer 710 may cover the side surface of the substrate 110. The static electricity prevention layer 710 may be aligned with the side surface of the substrate 110, the side surface of the first inorganic encapsulation layer 401, a side surface of the second inorganic encapsulation layer 403, and the side surface of the optical layer 460. In addition, as shown in FIG. 7 and FIG. 8, the static electricity prevention layer 710 may contact the first end 720_E of the plurality of first test wires 721. The static electricity prevention layer 710 may be formed by coating a conductive polymer compound on the side surface of the substrate 110 and the side surfaces of the plurality of first test wires 721. In an embodiment, the static electricity prevention layer 710 may be a coating layer of the conductive polymer compound, for example.

Hereinafter, referring to FIG. 9 to FIG. 12, a static electricity test wire of a display device in some embodiments will be described in detail.

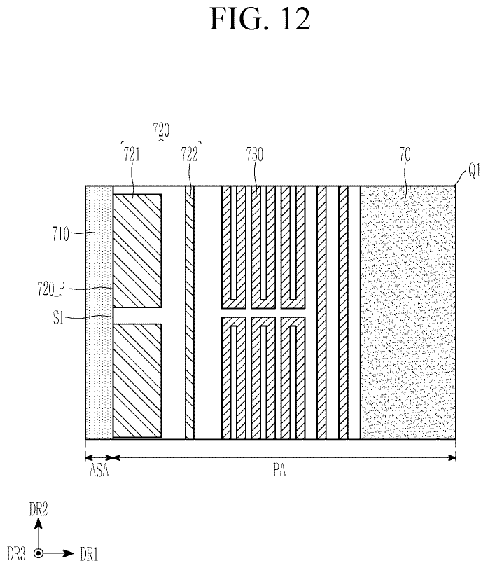

FIG. 9 to FIG. 11 are cross-sectional views corresponding to the region Q2 of FIG. 5, showing a static electricity test wire of a display device in some embodiments. FIG. 12 is a top plan view corresponding to the region Q1 of FIG. 3, showing a static electricity test wire of a display device in some embodiments.

First, referring to FIG. 9, the static electricity test wire 720 of a display device in some embodiments may be disposed between the first sub-gate insulating layer 120S and the second sub-gate insulating layer 122S. In an embodiment, the plurality of first test wires 721 and the second test wire 722 may be disposed directly on an upper surface of the first sub-gate insulating layer 120S, for example. The plurality of first test wires 721 and the second test wire 722 may be covered by the second sub-gate insulating layer 122S. That is, the side surfaces and the upper surfaces of the plurality of first test wires 721 and the side surface and the upper surface of the second test wire 722 may be covered by the second sub-gate insulating layer 122S. In some embodiments, the static electricity test wire 720 may be disposed in the same layer as the gate electrode 124, and may include the same material as that of the gate electrode 124. In an embodiment, the static electricity test wire 720 may include a metal such as copper (Cu), molybdenum (Mo), aluminum (Al), silver (Ag), chromium (Cr), tantalum (Ta), titanium (Ti), or the like, or a metal alloy, for example.

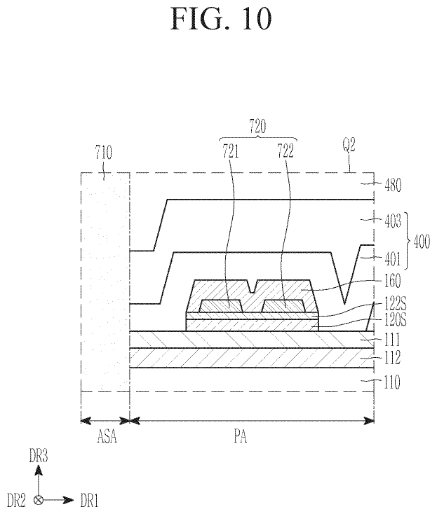

Referring to FIG. 10, at least a portion of the first sub-gate insulating layer 120S and at least a portion of the second sub-gate insulating layer 122S of a display device in some embodiments may not contact the static electricity prevention layer 710. In an embodiment, a side surface of the first sub-gate insulating layer 120S and a side surface of the second sub-gate insulating layer 122S may be surrounded by the first inorganic encapsulation layer 401, for example. That is, the first inorganic encapsulation layer 401 may be disposed between the static electricity prevention layer 710 and the first sub-gate insulating layer 120S and between the static electricity prevention layer 710 and the second sub-gate insulating layer 122S.

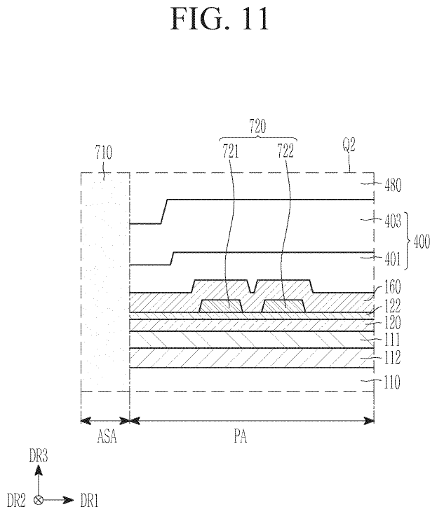

Referring to FIG. 11, the first gate insulating layer 120 and the second gate insulating layer 122 of a display device in some embodiments may extend up to the end of the substrate 110 in the first direction DR1. A side surface of the first gate insulating layer 120 and a side surface of the second gate insulating layer 122 may be aligned with the side surface of the substrate 110. The side surface of the first gate insulating layer 120 and the side surface of the second gate insulating layer 122 may contact the static electricity prevention layer 710. In this case, the static electricity test wire 720 may be disposed on the second gate insulating layer 122.

Referring to FIG. 12, the static electricity test wire 720 of a display device in some embodiments may have various shapes. In an embodiment, the plurality of first test wires 721 may have a quadrangular shape, e.g., rectangular shape, for example. At this time, the plurality of first test wires 721 may be arranged to be spaced apart in the second direction DR2, and a first surface of each of the plurality of first test wires 721 may contact the static electricity prevention layer 710. The first surface 720_P of each of the plurality of first test wires 721 may be aligned with the first side surface S1 of the substrate 110. However, but is not limited thereto, and the plurality of first test wires 721 may have a polygonal, circular, or elliptical shape, or the like.

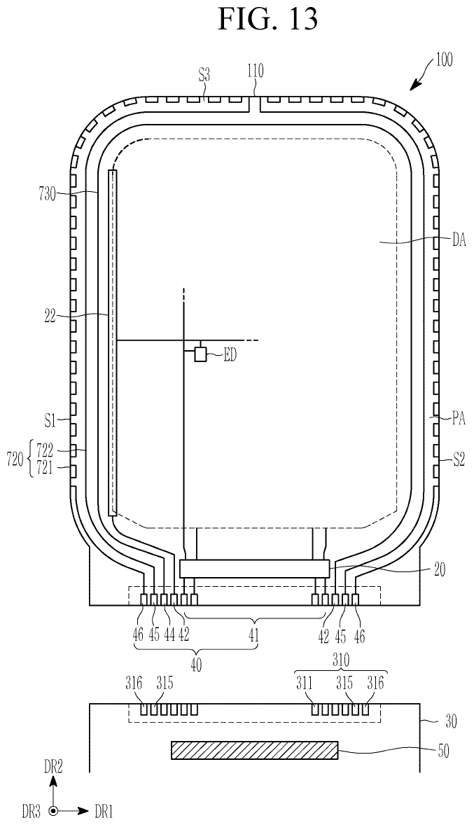

Hereinafter, referring to FIG. 13, a static electricity test wire of a display device in some embodiments will be described in detail.

Referring to FIG. 13, in some embodiments, the static electricity test wire 720 may surround the display area DA. In an embodiment, the static electricity test wire 720 may be arranged next (adjacent) to the first side surface S1 of the substrate 110, the second side surface S2 facing the first side surface S1 in the first direction DR1, and a third side surface S3 crossing the first side surface S1 and the second side surface S2, for example. Accordingly, the static electricity prevention layer 710 disposed on the first side surface S1, the second side surface S2, and the third side surface S3 of the substrate 110 may contact the plurality of first test wires 721. The second test wire 722 may be disposed between the crack test wire 730 and the plurality of first test wires 721.

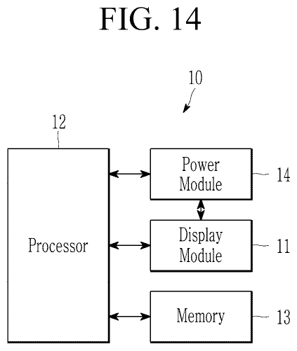

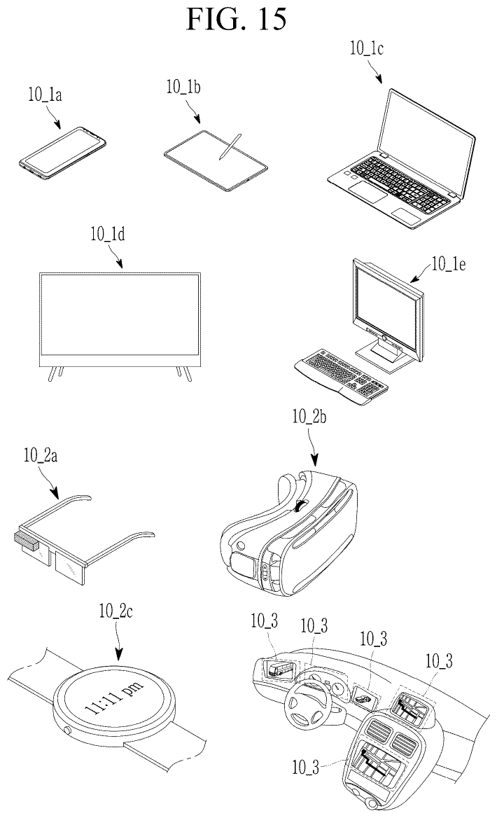

FIG. 14 is a block diagram illustrating an electronic device according to an embodiment. FIG. 15 is a view illustrating an embodiment of the electronic device of FIG. 14 implemented as a smartphone.

Referring to FIGS. 14 and 15, in an embodiment, an electronic device 1000 may include a processor 1010, a memory device 1020, a storage device 1030, an input/output (“I/O”) device 1040, a power supply 1050, and a display device 1060. Here, the display device 1060 may correspond to the display device 10 of FIG. 1. The electronic device 1000 may further include a plurality of ports for communicating with a video card, a sound card, a memory card, a universal serial bus (“USB”) device, or the like. In an embodiment, the electronic device 1000 may be implemented as a television. In another embodiment, the electronic device 1000 may be implemented as a smart phone. However, embodiments are not limited thereto, in another embodiment, the electronic device 1000 may be implemented as a cellular phone, a video phone, a smart pad, a smart watch, a tablet PC, a car navigation system, a computer monitor, a laptop, a head disposed (e.g., mounted) display (“HMD”), or the like.

The processor 1010 may perform various computing functions. In an embodiment, the processor 1010 may be a microprocessor, a central processing unit (“CPU”), an application processor (“AP”), or the like. The processor 1010 may be coupled to other components via an address bus, a control bus, a data bus, or the like. In an embodiment, the processor 1010 may be coupled to an extended bus such as a peripheral component interconnection (“PCI”) bus.

The memory device 1020 may store data for operations of the electronic device 1000. In an embodiment, the memory device 1020 may include at least one non-volatile memory device such as an erasable programmable read-only memory (“EPROM”) device, an electrically erasable programmable read-only memory (“EEPROM”) device, a flash memory device, a phase change random access memory (“PRAM”) device, a resistance random access memory (“RRAM”) device, a nano floating gate memory (“NFGM”) device, a polymer random access memory (“PoRAM”) device, a magnetic random access memory (“MRAM”) device, a ferroelectric random access memory (“FRAM”) device, or the like, and/or at least one volatile memory device such as a dynamic random access memory (“DRAM”) device, a static random access memory (“SRAM”) device, a mobile DRAM device, or the like.

In an embodiment, the storage device 1030 may include a solid state drive (“SSD”) device, a hard disk drive (“HDD”) device, a CD-ROM device, or the like. In an embodiment, the I/O device 1040 may include an input device such as a keyboard, a keypad, a mouse device, a touchpad, a touch-screen, or the like, and an output device such as a printer, a speaker, or the like.

The power supply 1050 may provide power for operations of the electronic device 1000. The power supply 1050 may provide power to the display device 1060. The display device 1060 may be coupled to other components via the buses or other communication links. In an embodiment, the display device 1060 may be included in the I/O device 1040.

In an embodiment the electronic device may be implemented as a smartphone. However the embodiments of the present disclosure may be exemplary and may not be limited to this. For example, the electronic device 1000 may be implemented as a mobile phone, a video phone, a smart pad, a smart watch, a television, a tablet PC, a vehicle display, a computer monitor, a notebook computer, a head-mounted display device, etc. In addition, the electronic device 1000 may be a television, a monitor, a notebook computer, or a tablet. In addition, the electronic device 1000 may be a car.

A display device according to an embodiment may be applied to various electronic devices. An electronic device according to an embodiment may include the display device, and may further include modules or devices having additional functions other than the display device.

FIG. 14 is a block diagram of an electronic device according to an embodiment. Referring to FIG. 14, the electronic device 10 according to an embodiment may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

The memory 15 may store data information necessary for operations of the processor 12 or the display module 11. When the processor 12 executes an application stored in the memory 15, video data signals and/or input control signals are transmitted to the display module 11, and the display module 11 can process the received signals to output video information through the display screen.

The power module 14 may include a power supply module such as a power adapter or battery device, and a power conversion module that converts the power supplied by the power supply module to generate the power necessary for the operation of the electronic device 10.

At least one of components of the electronic device 10 may be included within the display device according to the above-described embodiments. Additionally, some of the individual modules that are functionally included within a single module may be incorporated into the display device, while others may be provided separately from the display device. For example, the display device may include the display module 11, while the processor 12, memory 13, and power module 14 may be provided in a form of other devices within the electronic device 10 that are not part of the display device. FIG. 15 shows schematic diagrams of electronic devices according to various embodiments.

Referring to FIG. 15, various electronic devices with the display device according to the embodiments may include not only image display electronic devices such as smartphones 10_1a, tablet PCs 10_1b, laptops 10_1c, TVs 10_1d, desktop monitors 10_1e, but also wearable electronic devices with display modules such as smart glasses 10_2a, head-mounted displays 10_2b, smart watches 10_2c, as well as automotive electronic devices with display modules 10_3 such as those placed on car dashboards, center fascias, CID (Center Information Display), room mirror displays, and so on.

While this disclosure has been described in connection with what is presently considered to be practical embodiments, it is to be understood that the disclosure is not limited to the disclosed embodiments, but, on the contrary, is intended to cover various modifications and equivalent arrangements included within the spirit and scope of the appended claims.

What is claimed is:

1. A display device comprising:
a substrate comprising a display area and a peripheral area disposed outside a display area;
a light-emitting element disposed on the display area of the substrate;
a static electricity prevention layer which covers a side surface of the substrate; and
a static electricity test wire disposed on the peripheral area, the static electricity test wire comprising:
a plurality of first test wires spaced apart from each other and connected to the static electricity prevention layer, respectively; and
a second test wire electrically connected to the plurality of first test wires.

2. The display device of claim 1, wherein ends of the plurality of first test wires are aligned with an end of the substrate.

3. The display device of claim 1, wherein the plurality of first test wires is repeatedly arranged on an end of the substrate.

4. The display device of claim 1, further comprising:
a dam disposed on the peripheral area of the substrate; and
a crack test wire disposed between the dam and the static electricity test wire.

5. The display device of claim 4, wherein the second test wire is disposed between the plurality of first test wires and the crack test wire.

6. The display device of claim 4, wherein the static electricity test wire is disposed in a same layer as the crack test wire and comprises a same material as a material of the crack test wire.

7. The display device of claim 1, wherein each of the plurality of first test wires comprises horizontal portions in contact with the static electricity prevention layer and an extension portion connecting between the horizontal portions.

8. The display device of claim 1, further comprising:
a first gate insulating layer disposed on the substrate; and
a second gate insulating layer disposed on the first gate insulating layer,
wherein the plurality of first test wires and the second test wire are disposed on the second gate insulating layer.

9. The display device of claim 8, further comprising:
an inter-insulating layer disposed on the second gate insulating layer,
wherein the inter-insulating layer covers the plurality of first test wires and the second test wire.

10. The display device of claim 1, further comprising:
a first gate insulating layer disposed on the substrate;
a gate electrode disposed on the first gate insulating layer; and
a second gate insulating layer disposed on the gate electrode and the first gate insulating layer,
wherein the plurality of first test wires and the second test wire are disposed between the first gate insulating layer and the second gate insulating layer.

11. The display device of claim 10, wherein the plurality of first test wires and the second test wire comprise a same material as a material of the gate electrode.

12. The display device of claim 1, further comprising:
a driving circuit chip disposed on the peripheral area and configured to supply signal for driving the light-emitting element; and
a pad portion comprising a terminal electrically connected to the driving circuit chip, a first inspection terminal connected to the plurality of first test wires, and a second inspection terminal connected to the second test wire.

13. The display device of claim 12, further comprising a printed circuit board attached to an end of the substrate,
wherein the printed circuit board is electrically connected to the terminal electrically connected to the driving circuit chip, the first inspection terminal, and the second inspection terminal.

14. A display device comprising:
a display panel comprising:
a substrate comprising a display area and a peripheral area disposed outside the display area;
a light-emitting element disposed on the display area of the substrate; and
a static electricity test wire comprising:
a plurality of first test wires disposed on the peripheral area; and
a second test wire electrically connected to the plurality of first test wires
an optical layer disposed on a front surface of the display panel;
a cover window disposed on the optical layer;
a protection plate disposed on a rear surface of the display panel; and
a static electricity prevention layer covering a side surface of the display panel, a side surface of the optical layer, and a side surface of the protection plate,
wherein the plurality of first test wires is connected to the static electricity prevention layer, respectively.

15. The display device of claim 14, wherein ends of the plurality of first test wires are aligned with an end of the substrate.

16. The display device of claim 14, wherein the display panel further comprises:
a first gate insulating layer disposed on the substrate;
a gate electrode disposed on the first gate insulating layer; and
a second gate insulating layer disposed on the gate electrode and the first gate insulating layer,
wherein the plurality of first test wires and the second test wire are disposed on the second gate insulating layer.

17. The display device of claim 16, further comprising:
an inter-insulating layer disposed on the second gate insulating layer,
wherein the inter-insulating layer covers the plurality of first test wires and the second test wire.

18. The display device of claim 14, wherein the plurality of first test wires is arranged along a first direction, and the second test wire extends along the first direction.

19. The display device of claim 14, further comprising a crack test wire surrounding the display area of the substrate,
wherein the second test wire is disposed outside the crack test wire,
wherein the plurality of first test wires is disposed outside the second test wire, and
wherein the static electricity test wire is disposed in a same layer as the crack test wire, and comprises a same material as a material of the crack test wire.

20. An electronic device comprising:
a display device comprising:
a substrate comprising a display area and a peripheral area disposed outside a display area;
a light-emitting element disposed on the display area of the substrate;
a static electricity prevention layer configured to cover a side surface of the substrate; and
a static electricity test wire disposed on the peripheral area, the static electricity test wire comprising:
a plurality of first test wires spaced apart from each other and connected to the static electricity prevention layer, respectively; and
a second test wire electrically connected to the plurality of first test wires.
